(19) United States
(12) Patent Application Publication
(10) Pub. No.: US 2024/0223191 A1
(43) Pub. Date: Jul. 4, 2024

(54) NEGATIVE LEVEL SHIFTER AND DISPLAY DEVICE INCLUDING THE SAME

(71) Applicant: Magnachip Semiconductor, Ltd., Cheongju-si (KR)

(72) Inventors: Myung Woo LEE, Cheongju-si (KR); Woo Young LIM, Cheongju-si (KR)

(73) Assignee: Magnachip Semiconductor, Ltd., Cheongju-si (KR)

(21) Appl. No.: 18/383,584

(22) Filed: Oct. 25, 2023

(30) Foreign Application Priority Data
Jan. 2, 2023 (KR) 10-2023-0000075

(51) Int. Cl. H03K 19/0185; G09G 3/3225

(52) U.S. Cl. CPC H03K 19/018521; G09G 3/3225; G09G 2310/0289

(57) ABSTRACT

A negative level shifter that connects a source terminal and a body region of an element included in a shielding circuit so that the element operates within a medium voltage operating region. The negative level shifter of the present disclosure connects the source terminal and the body region of the shielding circuit so that the voltage between the drain terminal of the shielding circuit and the body region required for negative level shifting is operated in the medium voltage operating region. In addition, the negative level shifter may be able to use a medium voltage transistor rather than a high voltage transistor element provided in the input circuit so that the design area will be reduced compared to the conventional art. Also, the present disclosure suggests a display device with a negative level shifter.

### CROSS-REFERENCE TO RELATED APPLICATION

This application claims the priority of Korean Patent Application No. 10-2023-0000075 filed on Jan. 2, 2023, which is hereby incorporated by reference in its entirety.

### BACKGROUND

### Field of the Disclosure

The following description relates to a negative level shifter, more specifically, to a negative level shifter and a display device including the same. Although the present disclosure is suitable for a wide scope of applications, it is particularly suitable for a negative level shifter that connects a source terminal and a body region of an element included in a shielding circuit without using an additional negative voltage so that the element may operate in a medium voltage operating region and a display device including the same.

### Description of the Background

Due to IC processing technology miniaturization, the driver IC which controls display panel device driving is required to have a smaller size. Such driver IC uses negative voltage to drive the display panel device.

To use the negative voltage, the display driver circuit may require a level shifter for changing the low voltage signal entered in the logic region to the negative voltage signal. The level shifter is a device required to change and use a predetermined applied voltage to a required voltage.

When performing negative level shifting using the level shifter, each element should operate within its own operating regions. Korean Patent No. 10-2246879 may disclose the negative level shifting that does not require additional negative voltage and uses a shielding circuit so that the elements included in an input circuit and a load circuit may operate within the medium voltage operating region.

However, when using the maximum medium voltage as the negative voltage, the drain-body voltage of the element included in the shielding circuit exceeds the medium voltage operating regions. In other words, the PMOS transistor of the shielding circuit is connected to the positive power voltage (DVDD), in the shielding circuit, a voltage difference between the NMOS transistor's body region and the drain terminal exceeds the medium voltage operating region. In this case, the negative level shifter may not operate normally.

The above information disclosed in this Background section is only for enhancement of understanding of the background of the described technology and therefore it may contain information that does not form prior art that is already known to a person of ordinary skill in the art.

### SUMMARY

Accordingly, the present disclosure is directed to a negative level shifter and a display device including the same that substantially obviate one or more of problems due to limitations and disadvantages described above.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a negative level shifter includes a first level shifter including an input circuit, a shielding circuit, and a load circuit; and a second level shifter for generating a level different from a level of the first level shifter. The shielding circuit includes an NMOS transistor to which a source terminal and a body region are connected.

The input circuit may include a first PMOS transistor receiving an inverting input signal; and a second PMOS transistor receiving an input signal.

Body regions of the first PMOS transistor and the second PMOS transistor may be connected to each other.

The shielding circuit may include a first NMOS transistor connected to the first PMOS transistor through a first node; and a second NMOS transistor connected to the second PMOS transistor through a second node.

The first PMOS transistor and the second PMOS transistor may be high voltage elements. The first NMOS transistor and the second NMOS transistor may be medium voltage elements having a lower operating voltage than the high voltage element.

A first voltage may be applied to body regions of the first PMOS transistor and the second PMOS transistor. The first PMOS transistor and the second PMOS transistor may be formed in one well region.

A drain terminal of the first NMOS transistor may be connected to a first node, a gate terminal may be connected to ground, and a source terminal may be connected to a third node. A drain terminal of the second NMOS transistor may be connected to a second node, a gate terminal may be connected to ground, and a source terminal may be connected to a fourth node.

The load circuit may include: a third NMOS transistor including a drain terminal and a gate terminal connected to the third node and a source terminal connected to a fifth node; a fourth NMOS transistor including a drain terminal and a gate terminal connected to the fourth node and a source terminal connected to a sixth node; a fifth NMOS transistor including a drain terminal connected to the fifth node, a gate terminal connected to the fourth node, and a source terminal to which a negative voltage VNEG is applied; and a sixth NMOS transistor including a drain terminal connected to the sixth node, a gate terminal connected to the third node, and a source terminal to which a negative voltage VENG is applied. The negative voltage VENG may be applied to body regions of the third NMOS transistor to sixth NMOS transistor.

The second level shifter, when an inverting input signal of 0 V and a first voltage as an input signal are inputted to the first level shifter, may output a negative voltage through an inverting output terminal and output a ground voltage through an output terminal.

The second level shifter may include: a first PMOS transistor including a source terminal connected to ground (0 V), a gate terminal connected to an eighth node, and a drain terminal connected to a seventh node; a second PMOS transistor including a source terminal connected to ground (0 V), a gate terminal connected to a seventh node, and a drain terminal connected to the eighth node; a seventh NMOS transistor including a drain terminal connected to a seventh node, a gate terminal connected to a sixth node of the first level shifter, and a source terminal to which a negative voltage VNEG is applied; and an eighth NMOS transistor including a drain terminal connected to the eighth node, a gate terminal connected to a fifth node of the first level shifter, and a source terminal to which a negative voltage VNEG is applied.

The first PMOS transistor, the second PMOS transistor, the seventh NMOS transistor, and the eighth NMOS transistor may be medium voltage elements.

The input circuit may include a third PMOS transistor receiving an inverting input signal INB, and a fourth PMOS transistor receiving an input signal IN. The third PMOS transistor and the fourth PMOS transistor may be configured to be separated from each other in different well regions.

The third PMOS transistor and the fourth PMOS transistor may be medium voltage elements operating in a medium voltage operating region.

In another aspect of the present disclosure, a display device includes a display panel with a plurality of gate lines and a plurality of source lines; and a panel control circuit for driving the gate line and the source line.

The panel control circuit includes: a first level shifter including an input circuit, a shielding circuit, and a load circuit and a second level shifter connected to the load circuit. The shielding circuit includes NMOS transistors connected to a source terminal and a body region.

The input circuit may include a first PMOS transistor receiving an inverting input signal INB and a second PMOS transistor receiving an input signal IN. Body regions of the first PMOS transistor and the second PMOS transistor may be connected to each other.

The shielding circuit may include: a first NMOS transistor connected to the first PMOS transistor through a first node; and a second NMOS transistor connected to the second PMOS transistor through a second node, a source terminal and a body region of the first NMOS transistor are connected to each other, and a source terminal and a body region of the second NMOS transistor are connected to each other.

The shielding circuit may operate within a medium voltage operating region.

The first PMOS transistor and the second PMOS transistor may be high voltage elements. The first NMOS transistor and the second NMOS transistor may be medium voltage elements having a lower operating voltage than the high voltage element.

The second level shifter, when an inverting input signal of 0 V and a first voltage as an input signal are inputted to the first level shifter, may output a negative voltage and output a ground voltage through an output terminal.

The input circuit may include: a third PMOS transistor receiving an inverting input signal INB; and a fourth PMOS transistor receiving an input signal IN.

The third PMOS transistor and the fourth PMOS transistor may be configured to be separated from each other in different well regions.

This Summary section is provided to introduce a selection of concepts in a simplified form that are further described below in the Detailed Description. This Summary section is not intended to identify key features or essential features of the claimed subject matter, nor is it intended to be used as an aid in determining the scope of the claimed subject matter.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 illustrates a configuration diagram of a display panel device according to the present disclosure;

FIG. 2 illustrates a configuration diagram of interior of the source driver of FIG. 1;

FIG. 3 illustrates a circuit diagram of a negative level shifter according to an aspect of the present disclosure; and

FIG. 4 illustrates a circuit diagram of a negative level shifter according to another aspect of the present disclosure.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely aspects, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in aspects described herein may also be referred to as a second member, component, region, layer, or section without departing from the teachings of the aspects.

The terminology used herein is for describing various aspects only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

An expression representing a part of the terms such as “part” or “portion” used in the present disclosure may be used herein to describe a device that may include a specific function, software that may include a specific function, or a combination of devices and software that may include a specific function, and is not to be used to limit the described function. This is provided to help a more general understanding of the present disclosure, and various modifications and variations may be made from these descriptions by those of ordinary skill in the field to which the present disclosure belongs.

Additionally, it should be noted that all electric signals used in the present disclosure, as an aspect, may be reversed in signs of all electric signals to be described below when an inverter or the like is additionally provided in the circuit of the present disclosure. Therefore, the scope of the claims of the present disclosure is not limited to the direction of the signal.

The features of the aspects described herein may be combined in various ways as will be apparent after an understanding of the disclosure of this application. Further, although the aspects described herein have a variety of configurations, other configurations are possible as will be apparent after an understanding of the disclosure of this application.

The present disclosure is to provide a negative level shifter that allows a voltage between a drain terminal and a body region included in a shielding circuit required for negative level shifting to operate in a medium voltage operating region.

The present disclosure is to provide a display device with the negative level shifter.

The technical problems of the present disclosure are not limited to the technical problems mentioned above, and other technical problems not mentioned will be clearly understood by those skilled in the art from the following description.

Hereinafter, the present disclosure is described in more detail based on the aspect illustrated in the drawings.

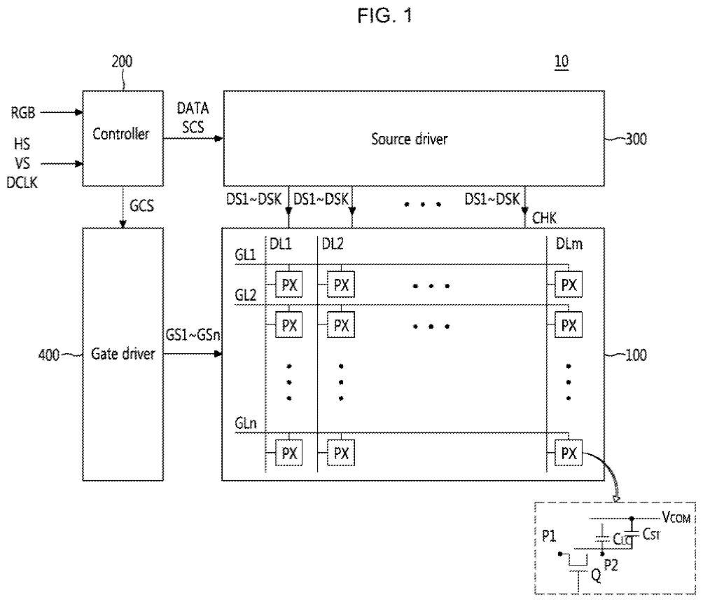

FIG. 1 illustrates a configuration diagram of a display device (or display panel device) according to an aspect of the present disclosure. A display device 10 includes a display panel 100, a controller 200, a source driver 300, and a gate driver 400.

The display device 10 may be a device capable of displaying an image or video. For example, the display device may refer to a smartphone, tablet personal computer, mobile phone, video phone, e-book reader, computer, camera, or wearable device, etc., but is not limited thereto.

The display panel 100 may include a plurality of sub-pixels PX arranged in rows and columns. In FIG. 1, the plurality of sub-pixels PX may be arranged in a matrix structure with n rows and m columns (n and m being natural numbers). The display panel 100 may be implemented as one of a Liquid Crystal Display (LCD), Light Emitting Diode (LED) display, Organic LED (OLED) display, Active-Matrix OLED (AMOLED) display, Electrochromic Display (ECD), Digital Mirror Device (DMD), Actuated Mirror Device (AMD), Grating Light Valve (GLV), Plasma Display Panel (PDP), Electro Luminescent Display (ELD), and Vacuum Fluorescent Display (VFD), but is not limited thereto.

The display panel 100 may include n gate lines GL1 to GLn arranged in n rows and m source (or data) lines DLI to DLm arranged in m columns. The sub-pixels PX may be disposed at intersections of gate lines GL1 to GLn and source (or data) lines DLI to DLm. Each sub-pixel includes a transistor Q connected to the gate lines GL1 to GLn and source (or data) lines DLI to DLm, a Liquid Crystal Capacitor (CLC) connected between the transistor Q and common power supply VCOM, and a storage capacitor CST. In detail, a gate line is connected to a gate terminal of the transistor Q included in each sub-pixel; a source line is connected to a first terminal P1 of the transistor Q; and a liquid crystal capacitor (CLC) and a storage capacitor CST are connected in parallel between a second terminal P2 and the common power supply VCOM. For example, the first terminal P1 of the transistor Q may be a source terminal, and the second terminal P2 may be a drain terminal.

The source driver 300 may generate data signals DS1 to DSk corresponding to an image displayed on the display panel 100 based on the image data DATA and transmit the generated data signals DS1 to DSk to the display panel 100. The data signals DS1 to DSk each may be transmitted to sub-pixels PX. For example, the source driver 300 may provide data signals DS1 to DSk to be displayed during 1H period to the sub-pixels PX driven during the 1H period.

The gate driver 400 may sequentially provide gate signals GS1 to GSn to a plurality of gate lines GL1 to GLn in response to a gate control signal GCS. For example, the gate control signal GCS may include a gate start pulse for indicating the start of the output of the gate signal, a gate shift clock for controlling the output timing of a gate on signal, etc.

The controller 200 may receive an image signal RGB from the outside, process the image signal RGB or convert the image signal RGB to fit the structure of the display panel to generate image data DATA. The controller 200 may transmit image data DATA to the source driver 300. The controller 200 may receive a plurality of control signals from an external host device. The control signals may include a horizontal synchronizing signal HS, a vertical synchronizing signal VS, and a clock signal DCLK. The controller 200 may generate a source control signal SCS and a gate control signal GCS for controlling the source driver 300 and gate driver 400 based on the received control signals. The controller 200 may control operating timings of the source driver 300 and gate driver 400 based on the source control signal SCS and the gate control signal GCS.

In FIG. 1, the controller 200, the source driver 300, and the gate driver 400 may be collectively referred to as a panel control circuit for controlling the display panel 100. Also, at least two of the controller 200, the source driver 300, and the gate driver 400 may be implemented as one integrated circuit. Additionally, according to aspects, the gate driver may be implemented by being mounted on the display panel 100.

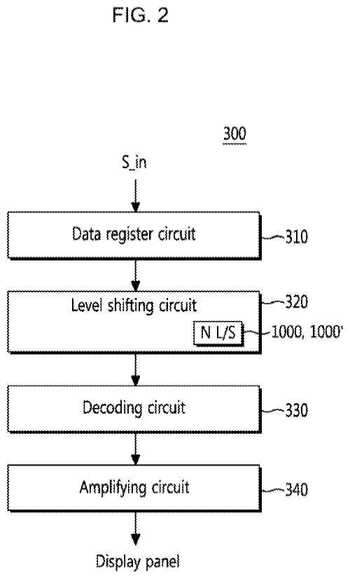

FIG. 2 illustrates a configuration diagram of the interior of the source driver of FIG. 1.

As shown in FIG. 2, the source driver 300 includes a data register circuit 310, a level shifting circuit 320, a decoding circuit 330, and an amplifying circuit 340.

The data register circuit 310 stores a digital image signal S_in to be displayed on the display panel 100.

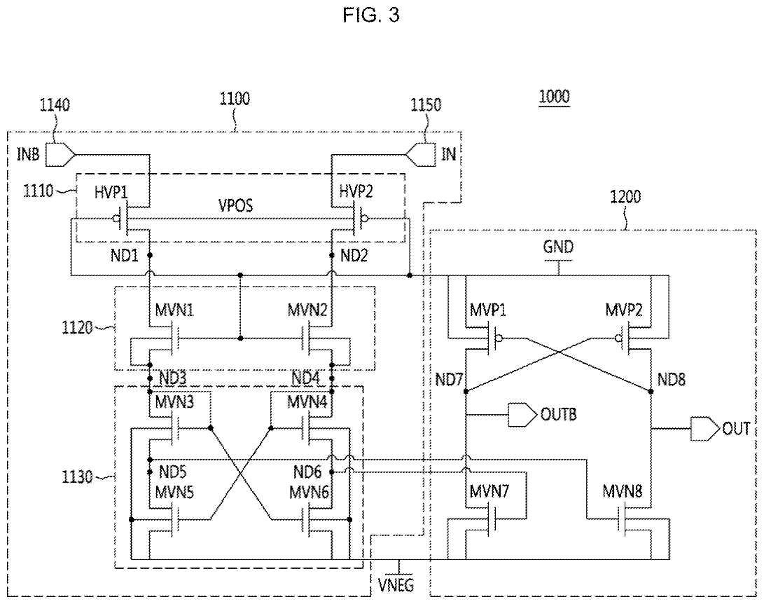

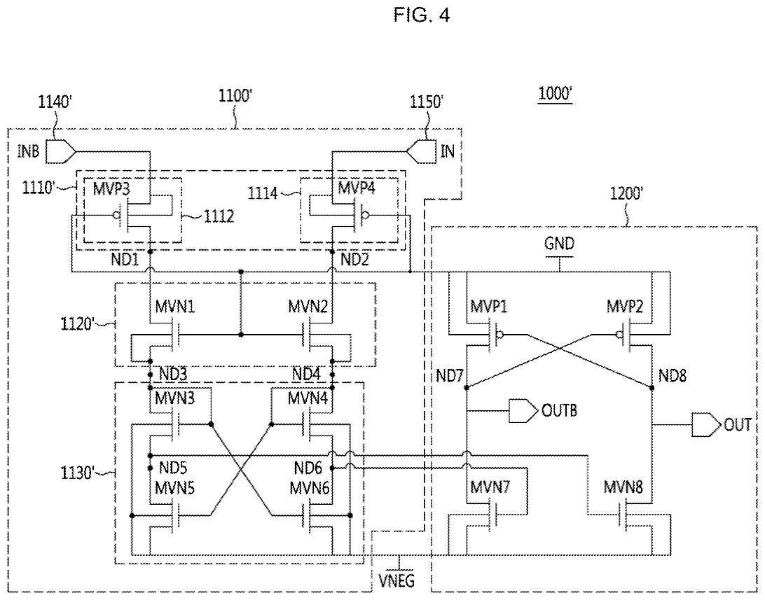

The level shifting circuit 320 converts the voltage level of the digital image signal outputted in the data register circuit 310. The level shifting circuit 320 includes negative level shifters N L/S; 1000, 1000′ (shown in FIGS. 3 and 4). The negative level shifters 1000, 1000′ may perform the negative level shifting process for the voltage level of the digital image signal from the data register circuit 310. It may be said that the present disclosure is a change in the structure of the negative level shifter circuit.

The decoding circuit 330 generates an analog grayscale voltage signal corresponding to the level-converted digital image signal inputted from the level shifting circuit 320. For example, the decoding circuit 330 receives the level-converted 8-bit digital image signal and outputs an analog grayscale voltage signal corresponding to the inputted level-converted 8-bit digital image signal.

The amplifying circuit 340 receives an analog grayscale voltage signal from the decoding circuit 330, and amplifies and outputs the inputted analog grayscale voltage signal.

FIG. 3 illustrates a circuit diagram of a negative level shifter according to an aspect of the present disclosure.

Referring to FIG. 3, a negative level shifter 1000 includes a first level shifter 1100 and a second level shifter 1200.

The first level shifter 1100 includes an input circuit 1110, a shielding circuit 1120, a load circuit 1130, an inverting input terminal 1140, and an input terminal 1150.

The input circuit 1110 includes two PMOS transistors HVP1, HVP2. According to one or more aspects, the PMOS transistors of a first HVP HVP1 and a second HVP HVP2 are high voltage devices. The high voltage device may be, For example, a device driven in a range of about 20 V to about 25 V.

In the input circuit 1110, an inverting input signal INB is input to a source terminal of the first HVP through the inverting input terminal 1140, the drain terminal is connected to a first node ND1, and the gate terminal is connected to ground 0 V.

The input signal IN is inputted to the source terminal of the second HVP through the input terminal 1150, the drain terminal is connected to a second node ND2, and the gate terminal is connected to the ground (i.e., 0 V). Also, body regions of the first HVP and the second HVP are connected to each other. A first voltage VPOS is applied to the body regions of the first HVP and the second HVP of the input circuit 1110.

The shielding circuit 1120 includes two NMOS transistors MVN1, MVN2. Regarding a first MVN MVN1, the drain terminal is connected to the first node ND1, the gate terminal is connected to the ground (i.e., 0 V), and the source terminal is connected to a third node ND3. According to one or more aspects of the present disclosure, the source terminal and the body region of the first MVN are connected to each other. Regarding a second MVN MVN2, the drain terminal is connected to the second node ND2, the gate terminal is connected to the ground (i.e., 0 V), and the source terminal is connected to a fourth node ND4. According to one or more aspects of the present disclosure, the source terminal and the body region of the second MVN are connected to each other. Connecting the source terminal and the body region of the first MVN and the second MVN respectively reduces the voltage between the drain terminal and the body region of the first MVN and the second MVN to operate in an operating region of the medium voltage (about 8 V). Accordingly, the voltage between the drain terminal and the body region of the first MVN and the second MVN does not exceed the intermediate voltage operation region.

The load circuit 1130 includes four NMOS transistors MVN3, MVN4, MVN5, MVN6. A drain terminal and a gate terminal of a third MVN MVN3 are connected to the third node ND3, and a source terminal is connected to a fifth node ND5. A drain terminal and a gate terminal of a fourth MVN MVN4 are connected to the fourth node ND4, and a source terminal is connected to a sixth node ND6. Regarding a fifth MVN MVN5, a drain terminal is connected to the fifth node ND5, a gate terminal is connected to the fourth node ND4, and a negative voltage VNEG is applied to the source terminal. Regarding a sixth MVN MVN6, a drain terminal is connected to the sixth node ND6, a gate terminal is connected to the third node ND3, and a negative voltage VNEG is applied to the source terminal. The negative voltage VNEG is applied to the bodies of the third to sixth MVNs.

According to aspects of the present disclosure, NMOS transistors of the shielding circuit 1120 and the load circuit 1130 are medium voltage elements driven in an operating region of a medium voltage (about 8 V) lower than the PMOS transistors of the first HVP and the second HVP. The medium voltage device may be a device driven in a voltage region where a voltage difference between the drain terminal and the body region is within about 8 V.

Referring to FIG. 3, the second level shifter 1200 includes two PMOS transistors MVP1, MVP2 and two NMOS transistors MVN7, MVN8. The PMOS transistors and NMOS transistors constituting the second level shifter 1200 may be medium voltage elements.

Regarding the first MVP MVP1, the source terminal is connected to the ground (i.e., 0 V), the gate terminal is connected to an eighth node ND8, and the drain terminal is connected to a seventh node ND7. Regarding the second MVP MVP2, the source terminal is connected to the ground (i.e., 0 V), the gate terminal is connected to the seventh node ND7, and the drain terminal is connected to the eighth node ND8. Regarding a seventh MVN MVN7, the drain terminal is connected to the seventh node ND7, the gate terminal is connected to the sixth node ND6 of the first level shifter 1100, and the negative voltage VNEG is applied to the source terminal. Regarding an eighth MVN MVN8, the drain terminal is connected to the eighth node ND8, the gate terminal is connected to the fifth node ND5 of the first level shifter 1100, and the negative voltage is applied to the source terminal.

Body regions of first MVP and second MVP, two PMOS transistors, are connected to ground (i.e., 0 V), and negative voltage VNEG is applied to body regions of seventh MVN and eighth MVN, two NMOS transistors.

According to aspects of the present disclosure, elements configured in the input circuit 1110, the shielding circuit 1120, and the load circuit 1130 of the first level shifter 1100 have structures symmetrical to each other, and elements included in the second level shifter 1200 also have structures symmetrical to each other. For example, the first HVP and the second HVP are designed to be symmetrical, the first, third, fifth, and seventh MVNs and the second, fourth, sixth, and eighth MVNs are designed to be symmetrical, and the first MVP and the second MVP are also designed to be symmetrical.

As described above, in the negative level shifter according to the present disclosure, the source terminal and the body region of the first MVN and the second MVN provided in the shielding circuit 1120 are connected to each other, and the first HVP and the second HVP, which are high voltage elements provided in the input circuit 1110, are connected to each other without separating the body region.

Referring to FIG. 3, a circuit operation of the negative level shifter will be described.

When a first voltage VPOS is input to the input terminal 1150 and 0 V is applied to the inverting input terminal 1140, the first HVP is turned off and the second HVP is turned on. Then, the second node ND2 to which the drain terminal of the second HVP is connected turns into a high-level state, and since the second MVN is turned on, the fourth node ND4 turns into a high-level state. At this time, the second MVN is an element provided in the shielding circuit 1120, and the voltage of the fourth node ND4 is limited to the voltage (GND−Vthn2) obtained by reducing a threshold voltage Vthn2 of the second MVN from the ground by the second MVN.

Accordingly, the voltage of GND−Vthn2 of the fourth node ND4 is applied to the gate terminal of the fifth MVN, and the fifth MVN is turned on. A fifth node ND5 connected to the drain terminal of the fifth MVN becomes a negative voltage VNEG. Also, the negative voltage VNEG of the fifth node ND5 is applied to the gate terminal of the eighth MVN of the second level shifter 1200. Then, the eighth MVN is turned off. Conversely, the third node ND3 between the first MVN and the third MVN becomes a voltage (Vthn3+VNEG) obtained by adding the threshold voltage Vthn3 of the third MVN and the negative voltage VNEG, and the sixth MVN is turned off by applying the voltage (Vthn3+VNEG) of the third node ND3 to the gate terminal of the sixth MVN. Therefore, the sixth node ND6 maintains the voltage of GND−(Vthn2+Vthn4), and the seventh MVN connected to the sixth node ND6 of the first level shifter 1100 is turned on by the sixth node voltage.

Therefore, when the seventh MVN is turned on, an inverting output terminal OUTB becomes a negative voltage VNEG. Accordingly, the seventh node ND7 is connected to the gate terminal of the second MVP, and the second MVP is turned on by the negative voltage VNEG. When the second MVP is turned on, the voltage of the output terminal OUT becomes 0 V.

As described above, in the level shifter 1000 according to aspects of the present disclosure, when the first voltage VPOS is applied to the input terminal 1150 and 0 V is applied to the inverting input terminal 1140, the output terminal outputs 0 V and the inverting output terminal 1140 outputs the negative voltage VNEG. In other words, the first voltage VPOS inputted to the input terminal 1150 is level-shifted to the ground voltage (i.e., 0 V), and the ground voltage (i.e., 0 V) inputted to the inverting input terminal 1140 is level-shifted to the negative voltage VNEG and outputted.

In the negative level shifter 1000 of the present disclosure, the voltage between the drain terminal and the body region of the NMOS transistor included in the shielding circuit 1120 is within an operating region of medium voltage (about 8 V). In detail, when the first voltage VPOS is inputted to the input terminal 1150 of the input circuit 1110 and 0 V is applied to the inverting input terminal 1140, the voltage between the drain terminal and the body region of MVN2 is maximally increased. At this time, the second node ND2 becomes the first voltage VPOS, and the voltage between the drain terminal and the body region of the second MVN becomes VPOS−(GND−Vthn2). For example, if VPOS=3 V and Vthn1=0.7 V, the voltage between the drain terminal and the body region of the second MVN is 3.7 V.

Conversely, when the first voltage VPOS is inputted to the inverting input terminal 1140 of the input circuit 1110 and 0 V is applied to the input terminal 1150, the voltage between the drain terminal and the body region of MVN1 is maximally increased. At this time, the first node ND1 becomes the first voltage VPOS, and the voltage between the drain terminal and the body region of the first MVN becomes VPOS−(GND−Vthn1). For example, if VPOS=3 V and Vthn1=0. 7 V, the voltage between the drain terminal and the body region of the first MVN becomes 3. 7 V. Since the maximum voltage between the drain terminal and the body region allowing the medium voltage element to operate is about 8 V, it may be seen that the first MNV and the second MVN are within the operating region of the medium voltage (about 8 V).

FIG. 4 illustrates a circuit diagram of a negative level shifter according to another aspect of the present disclosure.

Compared to the negative level shifter 1000 of FIG. 3, the negative level shifter 1000′ according to another aspect shown in FIG. 4 includes a first level shifter 1000′ and a second level shifter 1200′. In addition, the first level shifter 1100′ includes an input circuit 1110′, a shielding circuit 1120′ a load circuit 1130′, an inverting input terminal 1140′ and an input terminal 1150′.

However, the negative level shifter 1000′ of FIG. 4 includes a third MVP 1112 and a fourth MVP 1114, which are relatively small medium voltage elements, instead of a high voltage element HVP in the input circuit 1110′, and furthermore, the third MVP and the fourth MVP are designed by connecting each source terminal and the body region, which is different from the input circuit 1000 of FIG. 3. The source terminals and the body regions of the third and fourth MVPs are connected is to prevent voltages of the third and fourth MVPs from exceeding the operation region of the medium voltage. In addition, the use of the medium voltage element enables the design area to be smaller than using a high voltage element.

Unlike the aspect of FIG. 3, the input circuit 1110′ of FIG. 4 is designed for the third MVP and the fourth MVP to be separated from each other. As in the input circuit 1110′ of FIG. 4, even if it is necessary to design the well regions separately from each other, it is possible to design the negative level shifter according to the present disclosure while using the medium voltage element in the input circuit.

The operation of the negative level shifter 1000′ of FIG. 4 is omitted since it is performed in the same manner as the negative level shifter 1000 of FIG. 3.

As described above, the voltage between the drain terminal and the body region is reduced by connecting the source terminal and body region of the NMOS transistor provided in the shielding circuit of the negative level shifter, and transistor elements of an input circuit receiving an input signal may be designed as high voltage transistors or medium voltage transistors, and the negative level shifter may be manufactured according to the design specifications of the well region.

According to the present disclosure, by designing to connect the source terminal and body region included in the shielding circuit provided in the negative level shifter, the voltage between the drain terminal and the body region of the element does not exceed the medium voltage operation region.

According to the present disclosure, it is possible for a medium voltage transistor to be used instead of a high voltage transistor element provided in an input circuit of the negative level shifter, thereby reducing a design area.

While this disclosure includes specific aspects, it will be apparent after an understanding of the disclosure of this application that various changes in form and details may be made in these aspects without departing from the spirit and scope of the claims and their equivalents. The aspects described herein are to be considered in a descriptive sense only, and not for purposes of limitation. Descriptions of features or aspects in each aspect are to be considered as being applicable to similar features or aspects in other aspects. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A negative level shifter, comprising:
a first level shifter including an input circuit, a shielding circuit and a load circuit; and
a second level shifter configured to generate a level different from a level of the first level shifter,
wherein the shielding circuit includes an NMOS transistor having a source terminal and a body region connected to each other.

2. The negative level shifter of claim 1, wherein the input circuit comprises:
a first PMOS transistor configured to receive an inverting input signal; and
a second PMOS transistor configured to receive an input signal,
wherein body regions of the first PMOS transistor and the second PMOS transistor are connected to each other.

3. The negative level shifter of claim 2, wherein the shielding circuit comprises:
a first NMOS transistor connected to the first PMOS transistor through a first node; and
a second NMOS transistor connected to the second PMOS transistor through a second node.

4. The negative level shifter of claim 3, wherein the first PMOS transistor and the second PMOS transistor are high voltage elements, and
wherein the first NMOS transistor and the second NMOS transistor are medium voltage elements having an operating voltage lower than the high voltage elements.

5. The negative level shifter of claim 4, wherein a first voltage is applied to the body regions of the first PMOS transistor and the second PMOS transistor, and
wherein the first PMOS transistor and the second PMOS transistor are formed in a same well region.

6. The negative level shifter of claim 5, wherein the first NMOS transistor includes a drain terminal connected to a first node, a gate terminal connected to ground, and a source terminal connected to a third node, and
wherein the second NMOS transistor includes a drain terminal connected to a second node, a gate terminal connected to ground, and a source terminal connected to a fourth node.

7. The negative level shifter of claim 6, wherein the load circuit comprises:
a third NMOS transistor including a drain terminal and a gate terminal connected to the third node and a source terminal connected to a fifth node;
a fourth NMOS transistor including a drain terminal and a gate terminal connected to the fourth node and a source terminal connected to a sixth node;
a fifth NMOS transistor including a drain terminal connected to the fifth node, a gate terminal connected to the fourth node, and a source terminal to which a negative voltage is applied; and
a sixth NMOS transistor including a drain terminal connected to the sixth node, a gate terminal connected to the third node, and a source terminal to which the negative voltage is applied, and
wherein the negative voltage (VENG) is applied to body regions of the third NMOS transistor to sixth NMOS transistor.

8. The negative level shifter of claim 1, wherein, when an inverting input signal of 0 V and a first voltage as an input signal are inputted to the first level shifter, the second level shifter is configured to output a negative voltage through an inverting output terminal and output a ground voltage through an output terminal.

9. The negative level shifter of claim 8, wherein the second level shifter comprises:
a first PMOS transistor including a source terminal connected to a ground (0 V), a gate terminal connected to an eighth node, and a drain terminal connected to a seventh node;
a second PMOS transistor including a source terminal connected to the ground (0 V), a gate terminal connected to a seventh node, and a drain terminal connected to the eighth node;
a seventh NMOS transistor including a drain terminal connected to a seventh node, a gate terminal connected to a sixth node of the first level shifter, and a source terminal to which a negative voltage VNEG is applied; and
an eighth NMOS transistor including a drain terminal connected to the eighth node, a gate terminal connected to a fifth node of the first level shifter, and a source terminal to which a negative voltage is applied.

10. The negative level shifter of claim 9, wherein the first PMOS transistor, the second PMOS transistor, the seventh NMOS transistor, and the eighth NMOS transistor are medium voltage elements.

11. The negative level shifter of claim 1, wherein the input circuit comprises:
a third PMOS transistor receiving an inverting input signal; and
a fourth PMOS transistor receiving an input signal,
wherein the third PMOS transistor and the fourth PMOS transistor are separated from each other in different well regions.

12. The negative level shifter of claim 11, wherein the third PMOS transistor and the fourth PMOS transistor are medium voltage elements operating in a medium voltage operating region.

13. A display device, comprising:
a display panel with a plurality of gate lines and a plurality of source lines; and
a panel control circuit for driving the gate line and the source line;
wherein the panel control circuit includes: a first level shifter including an input circuit, a shielding circuit, and a load circuit and a second level shifter connected to the load circuit, and
wherein the shielding circuit includes NMOS transistors connected to a source terminal and a body region.

14. The display device of claim 13, wherein the input circuit includes a first PMOS transistor receiving an inverting input signal and a second PMOS transistor receiving an input signal, and
wherein body regions of the first PMOS transistor and the second PMOS transistor are connected to each other.

15. The display device of claim 14, wherein the shielding circuit comprises:
a first NMOS transistor connected to the first PMOS transistor through a first node; and
a second NMOS transistor connected to the second PMOS transistor through a second node, and
wherein a source terminal and a body region of the first NMOS transistor are connected to each other, and a source terminal and a body region of the second NMOS transistor are connected to each other.

16. The display device of claim 15, wherein the shielding circuit operates within a medium voltage operating region.

17. The display device of claim 16, wherein the first PMOS transistor and the second PMOS transistor are high voltage elements, and
wherein the first NMOS transistor and the second NMOS transistor are medium voltage elements having a lower operating voltage than the high voltage element.

18. The display device of claim 13, wherein the second level shifter, when an inverting input signal of 0 V and a first voltage as an input signal are inputted to the first level shifter, outputs a negative voltage and outputs a ground voltage through an output terminal.

19. The display device of claim 13, wherein the input circuit includes:
a third PMOS transistor receiving an inverting input signal; and
a fourth PMOS transistor receiving an input signal,
wherein the third PMOS transistor and the fourth PMOS transistor are configured to be separated from each other in different well regions.

20. The display device of claim 19, wherein the third PMOS transistor and the fourth PMOS transistor are elements operating in a medium voltage operating region, and
wherein source terminals and body regions are respectively connected.
